(19) United States
(12) Patent Application Publication
(10) Pub. No.: US 2026/0092362 A1
(43) Pub. Date: Apr. 2, 2026

(54) METHOD OF PROCESSING SUBSTRATE, METHOD OF MANUFACTURING SEMICONDUCTOR DEVICE, SUBSTRATE PROCESSING APPARATUS, AND RECORDING MEDIUM

(71) Applicant: Kokusai Electric Corporation, Tokyo (JP)

(72) Inventors: Haruki ARITA, Toyama-shi (JP); Makoto HIRANO, Toyama-shi (JP)

(73) Assignee: Kokusai Electric Corporation, Tokyo (JP)

(21) Appl. No.: 19/298,479

(22) Filed: Aug. 13, 2025

(30) Foreign Application Priority Data
Sep. 27, 2024 (JP) 2024-169451

(51) Int. Cl. C23C 16/44; C23C 16/04; C23C 16/52

(52) U.S. Cl. CPC C23C 16/4412; C23C 16/045; C23C 16/52

(57) ABSTRACT

There is provided a technique includes: (a) introducing a process gas stored in a reservoir into a process chamber; (b) maintaining a conductance of an exhaust flow path of the process chamber at a non-zero value for a predetermined time after starting the introduction of the process gas into the process chamber; and (c) after (b), increasing the conductance of the exhaust flow path of the process chamber to a value greater than the non-zero value maintained in (b).

### CROSS-REFERENCE TO RELATED APPLICATION

This application is based upon and claims the benefit of priority from Japanese Patent Application No. 2024-169451, filed on Sep. 27, 2024, the entire contents of which are incorporated herein by reference.

### TECHNICAL FIELD

The present disclosure relates to a method of processing a substrate, a method of manufacturing a semiconductor device, a substrate processing apparatus, and a recording medium.

### BACKGROUND

In the related art, for example, a substrate processing apparatus and a method of manufacturing a semiconductor device are known.

### SUMMARY

Some embodiments of the present disclosure provide a technique capable of suppressing degradation of a step coverage caused by a thermally decomposed process gas.

According to embodiments of the present disclosure, there is provided a technique includes (a) introducing a process gas stored in a reservoir into a process chamber; (b) maintaining a conductance of an exhaust flow path of the process chamber at a non-zero value for a predetermined time after starting the introduction of the process gas into the process chamber; and (c) after (b), increasing the conductance of the exhaust flow path of the process chamber to a value greater than the non-zero value maintained in (b).

### BRIEF DESCRIPTION OF DRAWINGS

The accompanying drawings, which are incorporated in and constitute a part of the specification, illustrate embodiments of the present disclosure.

FIG. 1 is a schematic configuration diagram of a vertical process furnace of a substrate processing apparatus suitably used in embodiments of the present disclosure, in which the portion of the process furnace is illustrated in a vertical sectional view.

FIG. 2 is a schematic configuration diagram of the vertical process furnace of the substrate processing apparatus suitably used in the embodiments of the present disclosure, in which the portion of the process furnace is illustrated in a sectional view taken along line A-A in FIG. 1.

FIG. 3 is a schematic configuration diagram of a controller of the substrate processing apparatus suitably used in the embodiments of the present disclosure, in which a control system of the controller is illustrated in a block diagram.

FIG. 4 is a diagram illustrating an APC valve and an APC controller used in the embodiments of the present disclosure.

FIG. 5 is a diagram illustrating a processing sequence in the embodiments of the present disclosure.

FIG. 6 is a diagram illustrating the pressure in a process chamber and the change over time in opening degree of an APC valve when a control operation in the embodiments of the present disclosure is performed.

FIG. 7 is a diagram illustrating the change in step coverage of a film formed on a substrate when various conditions are changed in the control operation in the embodiments of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to obscure aspects of the various embodiments.

### Embodiments of the Present Disclosure

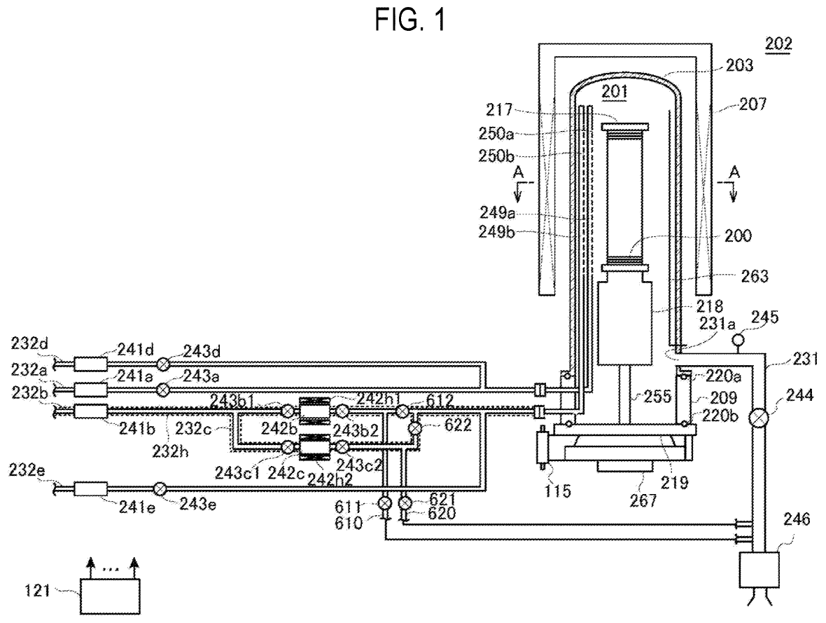

Embodiments of the present disclosure will be now described with reference to FIGS. 1 to 7. The drawings used in the following description are schematic, and the dimensional relationships of respective elements, the ratios of respective elements, and the like shown in the drawings may not match the actual ones. Furthermore, the dimensional relationships of respective elements, the ratios of respective elements, and the like may not match between multiple drawings.

### (Configuration)

As shown in FIG. 1, the process furnace 202 includes a heater 207 as a temperature regulator (heating part). The heater 207 is cylindrical and is installed vertically by being supported by a holding plate. The heater 207 also functions as an activation mechanism that activates a gas with heat.

Inside the heater 207, a reaction tube 203 is arranged concentrically with the heater 207. The reaction tube 203 is made of a heat-resistant material such as, for example, quartz (SiO₂) or the like, and is formed in a cylindrical shape with an upper end thereof closed and a lower end thereof opened. Below the reaction tube 203, a manifold 209 is arranged concentrically with the reaction tube 203. The manifold 209 is made of a metallic material such as stainless steel (SUS) or the like, and is formed in a cylindrical shape with upper and lower ends thereof opened. The upper end of the manifold 209 is engaged with the lower end of the reaction tube 203 and is configured to support the reaction tube 203. An O-ring 220a as a seal member is provided between the manifold 209 and the reaction tube 203. The reaction tube 203 is installed vertically just like the heater 207. A process container (reaction container) is mainly composed of the reaction tube 203 and the manifold 209. A process chamber 201 is formed in the hollow portion of the process container. The process chamber 201 is configured to accommodate wafers 200 as substrates. The wafers 200 are processed in the process chamber 201.

The boat 217 as a substrate support tool is configured to support a plurality of wafers 200, for example, 25 to 200 wafers 200, in a horizontal posture and in multiple stages while vertically arranging the wafers 200 with the centers thereof aligned with each other, i.e., to arrange the wafers 200 at intervals. A heat insulating part 218 made of a heat-resistant material such as, for example, quartz or the like is installed at the bottom of the boat 217.

A seal cap 219 as a furnace opening lid capable of airtightly closing the lower end opening of the manifold 209 is installed below the manifold 209. The seal cap 219 is made of a metallic material such as, for example, stainless steel or the like, and is formed in a disc shape. On the upper surface of the seal cap 219, there is installed an O-ring 220 b as a seal member which abuts against the lower end of the manifold 209. Below the seal cap 219, there is installed a rotator 267 for rotating a boat 217. A rotary shaft 255 of the rotator 267 is connected to the boat 217 through the seal cap 219. The rotator 267 is configured to rotate the wafers 200 by rotating the boat 217. The seal cap 219 is configured to be raised and lowered in the vertical direction by a boat elevator 115 as an elevating mechanism installed outside the reaction tube 203. The boat elevator 115 is configured as a transfer device (transfer mechanism) that loads and unloads (transfers) the wafers 200 into and out of the process chamber 201 by raising and lowering the seal cap 219.

Nozzles 249a and 249b as a first supply part and a second supply part are installed in the process chamber 201 so as to penetrate the side wall of the manifold 209. The nozzles 249a and 249b are also referred to as a first nozzle and a second nozzle, respectively. The nozzles 249a and 249b are respectively made of a heat-resistant material such as, for example, quartz or the like. The nozzles 249a and 249b are connected to gas supply pipes 232a and 232b, respectively. The nozzles 249a and 249b are installed adjacent to each other.

On the gas supply pipe 232a, a mass flow controller (MFC) 241a, which is a flow rate controller (flow rate control part), and a valve 243a, which is an opening/closing valve, are installed sequentially from the upstream side of a gas flow. On the gas supply pipe 232b, an MFC 241b, a valve 243b1, a tank 242b, which is a first reservoir, a valve 243b2, and a valve 612, are installed sequentially from the upstream side of the gas flow. The upstream end of the gas supply pipe 232c is connected to the gas supply pipe 232b on the downstream side of the MFC 241b and on the upstream side of the valve 243b1. On the gas supply pipe 232c, a valve 243c1, a tank 242c, which is a second reservoir, a valve 243c2, and a valve 622, are installed sequentially from the upstream side of the gas flow. The downstream end of the gas supply pipe 232c is connected to the gas supply pipe 232b on the downstream side of the valve 612. A vent pipe 610 may be connected to the gas supply pipe 232b on the downstream side of the valve 243b2 and on the upstream side of the valve 612. A vent pipe 620 may be connected to the gas supply pipe 232c on the downstream of the valve 243c2 and on the upstream of the valve 622. Valves 611 and 621 are installed on the vent pipes 610 and 620, respectively. The vent pipes 610 and 620 are connected to an exhaust pipe 231 on the downstream side of an APC valve 244, which will be described later. A gas supply pipe 232d is connected to the gas supply pipe 232a on the downstream of the valve 243a. A gas supply pipe 232e is connected to the gas supply pipe 232b on the downstream of the valve 612. On the gas supply pipes 232d and 232e, MFCs 241d and 241e and valves 243d and 243e are respectively installed sequentially from the upstream side of the gas flow. The gas supply pipes 232a to 232e and the vent pipes 610, 620 are made of, for example, a metallic material such as stainless steel or the like. Although the example in which one MFC 241b is installed for the tanks 242b and 242c has been shown here, the present disclosure is not limited thereto. The gas supply system may be configured such that one MFC is installed for each of the tanks 242b and 242c.

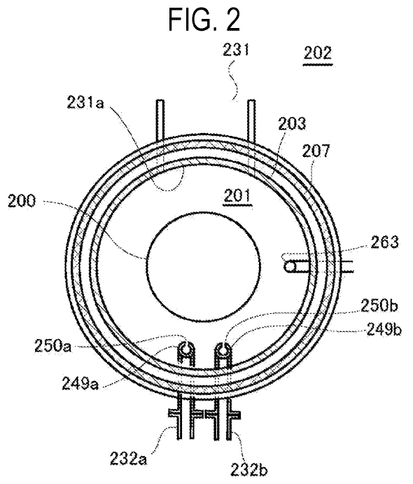

As shown in FIG. 2, the nozzles 249a and 249b are arranged in a space having an annular shape in a plane view between the inner wall of the reaction tube 203 and the wafers 200 and are installed to extend upward in the arrangement direction of the wafers 200 from the lower portion to the upper portion of the inner wall of the reaction tube 203. In other words, the nozzles 249a and 249b are respectively installed in a region horizontally surrounding a wafer arrangement region, in which the wafers 200 are arranged, on the lateral side of the wafer arrangement region so as to extend along the wafer arrangement region. Gas supply holes 250a and 250b for supplying gases are formed on the side surfaces of the nozzles 249a and 249b, respectively. The gas supply holes 250a and 250b are respectively opened so as to face the centers of the wafers 200 in a plane view and can supply gases toward the wafers 200. The gas supply holes 250a and 250b are formed from the lower portion to the upper portion so as to correspond to the plurality of wafers 200.

The tanks 242b and 242c are configured as gas tanks having an intentionally increased capacity compared to typical pipes. By opening and closing the valves 243b1 and 243c1 on the upstream side of the tanks 242b and 242c and the valves 243b2 and 243c2 on the downstream side of the tanks 242b and 242c, the gases supplied from the gas supply pipes 232b and 232c can be temporarily filled (stored) in the tanks 242b and 242c, respectively, and the gases temporarily stored in the tanks 242b and 242c can be supplied into the process chamber 201.

By closing the valves 243b2, 243c1 and 243c2 and opening the valve 243b1, the gas whose flow rate has been regulated by the MFC 241b can be temporarily stored in the tank 242b. After a predetermined amount of gas is stored in the tank 242b and the pressure in the tank 242b reaches a predetermined pressure, the valve 243b1 is closed and the valves 243b2 and 612 are opened, so that the high-pressure gas stored in the tank 242b can be supplied at once (in a short time) to the process chamber 201 via the gas supply pipe 232b and the nozzle 249b. In addition, by closing the valves 243b1, 243b2 and 243c2 and opening the valve 243c1, the gas whose flow rate has been regulated by the MFC 241b can be temporarily stored in the tank 242c. After a predetermined amount of gas is stored in the tank 242c and the pressure in the tank 242c reaches a predetermined pressure, the valve 243c1 is closed and the valves 243c2 and 622 are opened, so that the high-pressure gas stored in the tank 242c can be supplied at once (in a short time) to the process chamber 201 through the gas supply pipes 232c and 232b and the nozzle 249b. Furthermore, by closing the valves 243b1 and 612 and opening the valves 243b2 and 611, the gas temporarily stored in the tank 242b can be bypassed without passing through the process chamber 201 and can be exhausted to the exhaust pipe 231 through the vent pipe 610. In addition, by closing the valves 243c1 and 622 and opening the valves 243c2 and 621, the gas temporarily stored in the tank 242c can be bypassed without passing through the process chamber 201 and can be exhausted to the exhaust pipe 231 through the vent pipe 620.

Heaters 242h1 and 242h2 serving as first and second heating parts for heating the tanks 242b and 242c are provided around the outer periphery of the tanks 242b and 242c, respectively. By heating the tanks 242b and 242c with the heaters 242h1 and 242h2, the gases stored in the tanks 242b and 242c can be heated.

As shown in FIG. 1, for example, ribbon-shaped heaters 232h are wound around the outer peripheries of the gas supply pipes 232b and 232c, for example, the outer peripheries of the gas supply pipes 232b and 232c on the front stage (upstream side) and rear stage (downstream side) of the tanks 242b and 242c, as third heating parts for heating them. It is desirable for the heaters 232h to heat the entire wetted surface of the gas supply pipes so as to prevent liquefaction due to compression or sudden expansion of a gas.

A first process gas as a reactant is supplied from the gas supply pipe 232a through the MFC 241a, the valve 243a, and the nozzle 249a into the process chamber 201. The first process gas is used as one of film-forming agents.

A second process gas as a precursor is supplied from the gas supply pipe 232b through the MFC 241b, the valve 243b1, the tank 242b, the valves 243b2 and 612, and the nozzle 249b into the process chamber 201. Furthermore, the second process gas as a precursor is supplied from the gas supply pipe 232b through the MFC 241b, the gas supply pipe 232c, the valve 243c1, the tank 242c, the valves 243c2 and 622, and the nozzle 249b into the process chamber 201. The second process gas is used as one of the film-forming agents.

An inert gas is supplied from the gas supply pipes 232d and 232e into the process chamber 201 via the MFCs 241d and 241e, the valves 243d and 243e, the gas supply pipes 232a and 232b, and the nozzles 249a and 249b, respectively. The inert gas acts as a purge gas, a carrier gas, a dilution gas, or the like.

A first supply system (reactant supply system) is mainly composed of the gas supply pipe 232a, the MFC 241a, and the valve 243a. A second supply system (first precursor supply system) is mainly composed of the gas supply pipe 232b, the MFC 241b, the valve 243b1, the tank 242b, and the valve 243b2. A third supply system (second precursor supply system) is mainly composed of the gas supply pipe 232c, the valve 243c1, the tank 242c, and the valve 243c2. The gas supply pipe 232b and the MFC 241b may be included in the third supply system. An inert gas supply system is mainly composed of the gas supply pipes 232d and 232e, the MFCs 241d and 241e, and the valves 243d and 243e. Each or the entirety of the first to third supply systems is also referred to as a film-forming agent supply system.

An exhaust port 231 for exhausting the atmosphere in the process chamber 201 is provided in the lower portion of the side wall of the reaction tube 203. As shown in FIG. 2, the exhaust port 231a is provided at a position that faces the nozzles 249a and 249b (gas supply holes 250a and 250b) across the wafer 200 in a plane view. The exhaust port 231a may be provided to extend from the lower portion to the upper portion of the side wall of the reaction tube 203, i.e., along the wafer arrangement region. An exhaust pipe 231 is connected to the exhaust port 231a. A vacuum pump 246 as an evacuation device is connected to the exhaust pipe 231 via a pressure sensor 245 as a pressure detector (pressure detection part) for detecting the pressure in the process chamber 201 and an APC (Auto Pressure Controller) valve 244 as a pressure regulator (pressure regulation part). The APC valve 244 is configured so that it can perform or stop vacuum evacuation of the interior of the process chamber 201 by being opened and closed in a state in which the vacuum pump 246 is operated. Furthermore, the APC valve 244 is configured so that it can regulate the pressure in the process chamber 201 by adjusting the valve opening degree based on the pressure information detected by the pressure sensor 245 in a state in which the vacuum pump 246 is operated. A process gas exhaust system is mainly constituted by the exhaust pipe 231, the APC valve 244 and the pressure sensor 245. The vacuum pump 246 may be included in the process gas exhaust system. The exhaust pipe 231 between the exhaust port 231a and the vacuum pump 246 constitutes an exhaust flow path.

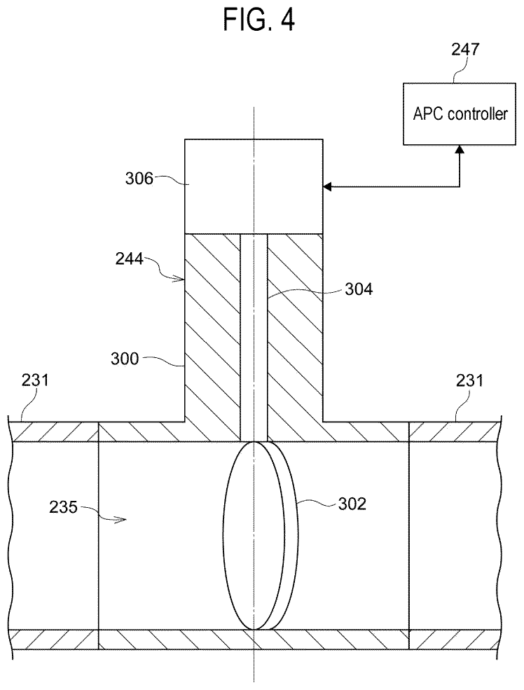

As shown in FIG. 4, a so-called butterfly valve is used as the APC valve 244. More specifically, the APC valve 244 includes a main body 300, a valve body 302, a drive shaft 304, and a servo motor 306.

As shown in FIG. 4, the main body 300 is a member to which the valve body 302, the drive shaft 304, and the servo motor 306 are attached. The main body 300 includes a flow path 235, and is connected to the exhaust pipe 231 on both sides of the flow path 235. In other words, the main body 300 is inserted into the exhaust pipe 231.

As shown in FIG. 4, the valve body 302 is arranged inside the main body 300. More specifically, the valve body 302 is a plate member that rotates about a direction of a rotation axis perpendicular to the direction of the fluid (i.e., exhaust gas) flowing through the exhaust pipe 231. The valve body 302 changes the area of the valve body 302 projected onto the flow path 235 inside the flow path 235 of the main body 300, thereby changing the conductance of the fluid flowing through the flow path 235.

As shown in FIG. 4, the drive shaft 304 is a shaft extending along the rotation axis of the valve body 302, and is configured to connect the servo motor 306 and the valve body 302. The drive shaft 304 transmits the rotation torque of the servo motor 306 to the valve body 302.

The servo motor 306 generates a torque acting in the forward rotation direction and a torque acting in the reverse rotation direction under the control operation of the APC controller 247. The servo motor 306 of the APC valve 244 is electrically connected to the APC controller 247, and is rotationally driven by the power supplied from the APC controller 247. The servo motor 306 also communicates with the APC controller 247 to transmit the rotation angle of the servo motor 306, i.e., the rotation angle of the valve body 302, which is the opening degree of the flow path 235, to the APC controller 247.

In the present embodiments, the APC valve 244 preferably has a nominal diameter of 150 A or more, for example.

The APC valve 244 is controlled by the controller 121 via the APC controller 247, as described below.

Inside the reaction tube 203, there is installed a temperature sensor 263 as a temperature detector. By regulating the state of supply of electric power to the heater 207 based on the temperature information detected by the temperature sensor 263, the temperature inside the process chamber 201 becomes a desired temperature distribution. The temperature sensor 263 is installed along the inner wall of the reaction tube 203.

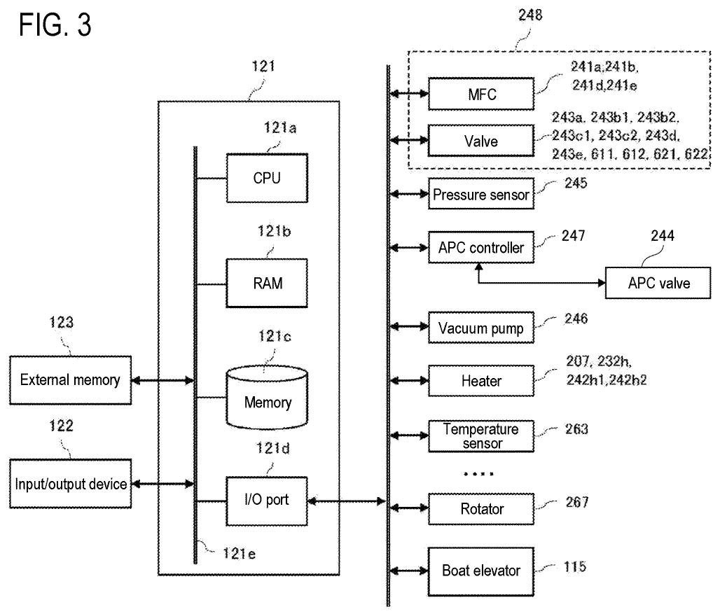

As shown in FIG. 3, the controller 121 as a control part (control means) is configured as a computer including a CPU (Central Processing Unit) 121a, a RAM (Random Access Memory) 121b, a memory 121c and an I/O port 121d. The RAM 121b, the memory 121c and the I/O port 121d are configured to exchange data with the CPU 121a via an internal bus 121e. An input/output device 122 configured as, for example, a touch panel or the like is connected to the controller 121. Further, an external memory 123 may be connected to the controller 121.

The memory 121c is composed of, for example, a flash memory, an HDD (Hard Disk Drive), an SSD (Solid State Drive), or the like. In the memory 121c, there are readably stored a control program for controlling the operation of the substrate processing apparatus, a process recipe in which procedures and conditions of substrate processing to be described later are written, and the like. The process recipe is a combination of instructions for causing the controller 121 to have the substrate processing apparatus execute the respective procedures in a below-described substrate processing process so as to obtain a predetermined result. The process recipe functions as a program. Hereinafter, the process recipe, the control program, and the like are collectively and simply referred to as a program. Furthermore, the process recipe is also simply referred to as a recipe. When the term “program” is used herein, it may mean a case of solely including the recipe, a case of solely including the control program, or a case of including both the recipe and the control program. The RAM 121b is configured as a memory area (work area) in which programs, data and the like read by the CPU 121a are temporarily held.

The I/O port 121d is connected to the MFCs 241a, 241b, 241d and 241e, the valves 243a, 243b1, 243b2, 243c1, 243c2, 243d, 243e, 611, 612, 621 and 622, the pressure sensor 245, the APC valve 244, the vacuum pump 246, the temperature sensor 263, the heater 207, the rotator 267, the boat elevator 115, and the like.

The CPU 121a is configured to read and execute the control program from the memory 121c and to read the recipe from the memory 121c in response to an input of an operation command from the input/output device 122 or the like. The CPU 121a is configured to, according to the contents of the recipe thus read, control the flow rate regulation operation for various gases by the MFCs 241a, 241b and 241d, the opening/closing operations of the valves 243a, 243b1, 243b2, 243c1, 243c2, 243d, 243e, 611, 612, 621 and 622, the opening/closing operation of the APC valve 244, the pressure regulation operation by the APC valve 244 based on the pressure sensor 245, the start and stop of the vacuum pump 246, the temperature regulation operation of the heater 207 based on the temperature sensor 263, the rotation and the rotation speed adjustment operation of the boat 217 by the rotator 267, the raising and lowering operation of the boat 217 by the boat elevator 115, and the like.

The controller 121 may be configured by installing, in the computer, the above-described program (program product) recorded and stored in an external memory 123. The external memory 123 includes, for example, a magnetic disk such as an HDD or the like, an optical disk such as a CD or the like, a magneto-optical disk such as an MO or the like, a semiconductor memory such as a USB memory, an SSD or the like, and so forth. The memory 121c and the external memory 123 are configured as a computer readable recording medium. Hereinafter, the memory 121c and the external memory 123 are collectively and simply referred to as a recording medium. The provision of the program to the computer may be performed by using a communication means such as the Internet or a dedicated line without having to use the external memory 123.

In addition, the controller 121 may directly control the opening degree of the APC valve244 via the APC controller 247.

As shown in FIG. 3, the APC controller 247 receives a signal from the pressure sensor 245, and controls the APC valve 244 based on the signal and the target pressure value or the opening command received from the controller 121. More specifically, as shown in FIG. 4, the APC controller 247 supplies electric power to drive the servo motor 306 included in the APC valve 244. The servo motor 306 changes the angle of the valve body 302 in the flow path 235 based on the electric power supplied from the APC controller 247. In other words, when electric power is supplied from the APC controller 247, the servo motor 306 drives the valve body 302 installed in the flow path 235 of the exhaust system to change the opening degree of the flow path 235, thereby controlling the conductance of the exhaust system.

### Substrate Processing Method

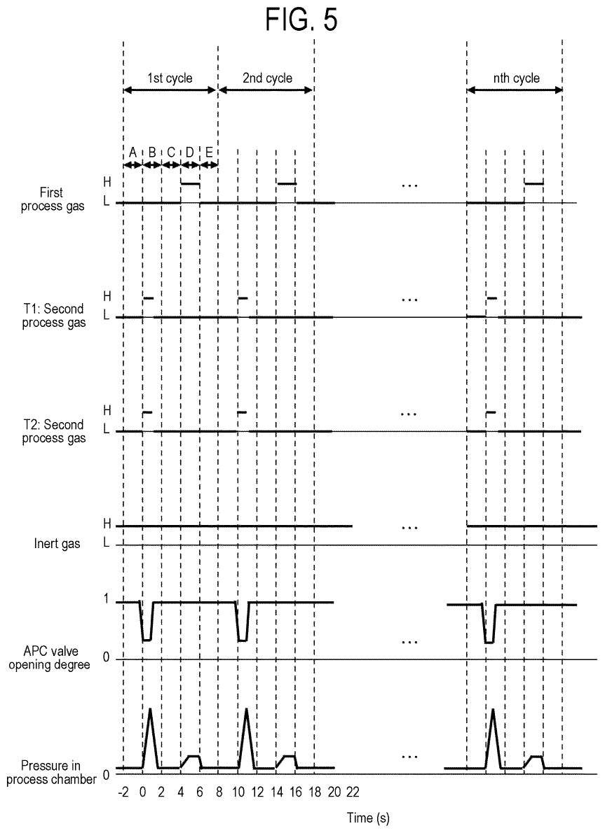

Next, a method of processing a substrate using the substrate processing apparatus 100 according to embodiments of the present disclosure will be described with reference to FIG. 5. Here, as an example of a semiconductor device manufacturing process, a cycle process in which a source gas (precursor gas) and a reactant (reaction gas) are supplied to the process chamber 201 to perform processing will be described. In these embodiments, an example in which a film is formed on a wafer 200 will be described. More specifically, a film-forming process in which a first process gas and a second process gas are used to form a film on a substrate including a recess such as a trench or a hole will be described.

The term “wafer” used herein may refer to a wafer itself or a stacked body of a wafer and a predetermined layer or film formed on the surface of the wafer. The phrase “a surface of a wafer” used herein may refer to a surface of a wafer itself or a surface of a predetermined layer or the like formed on a wafer. The expression “a predetermined layer is formed on a wafer” used herein may mean that a predetermined layer is directly formed on a surface of a wafer itself or that a predetermined layer is formed on a layer or the like formed on a wafer. The term “substrate” used herein may be synonymous with the term “wafer.”

Furthermore, as used herein, the term “agent” includes at least one selected from the group of a gaseous substance and a liquid substance. The liquid substance includes a mist-like substance. That is, the film-forming agents (the precursor and the reactant) may include a gaseous substance, a liquid substance such as a mist-like substance or the like, or both.

In addition, as used herein, the term “layer” includes at least one selected from the group of a continuous layer and a discontinuous layer. The layer formed in each step described later may include a continuous layer, a discontinuous layer, or both.

Although not shown in FIG. 5, in the method of processing a substrate of these embodiments, the wafer 200 is prepared in advance in the process chamber 201. The inside of the process chamber 201 is evacuated (depressurized) by the vacuum pump 246 to a desired pressure (vacuum level). The pressure in the process chamber 201 is measured by the pressure sensor 245.

FIG. 5 shows the timings at which the first process gas, the second process gas, and the inert gas are supplied to the process chamber 201 in these embodiments. More specifically, the “first process gas” in FIG. 5 indicates the operation of the valve 243a that supplies the first process gas. That is, when the “first process gas” is in an “H” state, the valve 243a is opened and the first process gas is supplied into the process chamber 201. When the “first process gas” is in a “L” state, the valve 243a is closed and the supply of the first process gas is stopped. The same applies to the “second process gas” and the “inert gas.”

Furthermore, the APC valve opening degree is indicated by values from 0 to 1, wherein the APC valve opening degree “0” indicates that the APC valve 244 is closed and the flow path 235 is blocked. The APC valve opening degree “1” indicates that the APC valve 244 is fully open and the flow path 235 is most open. In other words, the APC valve opening degree in FIG. 5 indicates the conductance of the exhaust system as a dimensionless quantity.

The horizontal axis in FIG. 5 represents the time. The time when the supply of the second process gas starts (more precisely, the time when the valves 612, 622, and the like are opened) is set as “0”.

The second process gas may be, for example, a second process gas containing a predetermined element such as tungsten (W), titanium (Ti), molybdenum (Mo), tantalum (Ta), cobalt (Co), yttrium (Y), ruthenium (Ru), hafnium (Hf), zirconium (Zr), aluminum (Al), silicon (Si), or the like. As the second process gas, one or more of these gases may be used. As the second process gas, a gas excited by plasma of these gases or the like may be used.

The second process gas may be, for example, a halogen-based second process gas containing a predetermined element and a halogen element. The halogen-based second process gas may be, for example, gases containing tungsten hexachloride (WCl₆), tungsten hexafluoride (WF₆), titanium tetrachloride (TiCl₄), titanium tetrafluoride (TiF₄), molybdenum pentachloride (MoCl₅), molybdenum pentafluoride (MoF₅), molybdenum dioxide dichloride (MoO₂Cl₂), molybdenum oxide tetrachloride (MoOCl₄), tantalum pentachloride (TaCl₅), tantalum pentafluoride (TaF₅), cobalt difluoride (CoF₂), cobalt dichloride (CoCl₂), yttrium trifluoride (YF₃), yttrium trichloride (YCl₃), ruthenium trichloride (RuCl₃), ruthenium trifluoride (RuF₃), hafnium tetrachloride (HfCl₄), hafnium tetrafluoride (HfF₄), zirconium tetrachloride (ZrCl₄), zirconium tetrafluoride (ZrF₄), aluminum trichloride (AlCl₃), aluminum trifluoride (AlF₃), dichlorosilane (SiH₂Cl₂), 1,2-dichlorodisilane (Si₂H₄Cl₂), 1,1,1-trichlorodisilane (Si₂H₃Cl₃), 1,1,2-trichlorodisilane (Si₂H₃Cl₃), pentachlorodisilane (Si₂HCl₅), hexachlorodisilane (Si₂Cl₆), tetrafluorosilane (SiF₄), or the like. Furthermore, the second process gas may be, for example, gases containing monosilane (SiH₄), disilane (Si₂H₆), trisilane (Si₃H₈), tetrasilane (Si₄H₁₀), or the like. One or more of these gases may be used as the second process gas.

The second process gas may be, for example, an organic predetermined element-containing gas including a predetermined element and an organic ligand.

The first process gas may be, for example, gases including a reducing gas, an oxidizing gas, a nitriding gas, a sulfide gas, a selenide gas, a telluride gas, or the like. As the first process gas, one or more of these gases may be used. As the first process gas, a gas obtained by exciting these gases by plasma or the like may be used. For example, when one of the first process gas and the second process gas is a gas containing a specific element and the other is a reducing gas, a film composed of a specific element alone may be formed on the substrate. In addition, for example, when one of the first process gas and the second process gas is a gas containing a specific element and the other is any one of an oxidizing gas, a nitriding gas, a sulfide gas, a selenide gas, and a telluride gas, an oxide film of a specific element, a nitride film of a specific element, a sulfide film of a specific element, a selenide film of a specific element, and a telluride film of a specific element may be formed on the wafer.

The first process gas may be, for example, one or more of gases including a hydrogen (H₂) gas, a deuterium (D₂) gas, a borane (BH₃) gas, a diborane (B₂H₆) gas, a carbon monoxide (CO) gas, an ammonia (NH₃) gas, a monosilane (SiH₄) gas, a disilane (Si₂H₆) gas, a trisilane (Si₃H₈) gas, a monogermane (GeH₄) gas, a digermane (Ge₂H₆), and the like. In addition, as the first process gas, for example, an oxidizing gas of an oxygen (O)-containing gas may be used. The oxidizing gas may be, for example, one or more of gases including oxygen (O₂), ozone (O₃), water vapor (H₂O), a mixed gas of H₂ and O₂, hydrogen peroxide (H₂O₂), nitrous oxide (N₂O), and the like. The nitriding gas may be, for example, one or more of hydrogen nitride gases such as an ammonia (NH₃) gas, a diazene (N₂H₂) gas, a hydrazine (N₂H₄) gas, an N₃H₈ gas, and the like. The sulfurizing gas may be, for example, gases containing sulfane (H₂S), disulfane (H₂S₂), diammonium sulfide ((NH₄)₂S), dimethyl sulfide ((CH₃)₂S), and the like. As the sulfurizing gas, one or more of these gases may be used. The selenizing gas may be, for example, gases containing selenium (H₂Se), diselane (H₂Se₂), dimethylselenium ((CH₃)₂Se), and the like. As the selenizing gas, one or more of these gases may be used. The tellurizing gas may be, for example, gases containing terane (H₂Te), diterane (H₂Te₂), dimethylselenium ((CH₃)₂Te), and the like. As the tellurizing gas, one or more of these gases may be used.

The inert gas may be, for example, rare gases such as a helium (He) gas, an argon (Ar) gas, a neon (Ne) gas, a xenon (Xe) gas, and the like, or a nitrogen (N₂) gas. As the inert gas, one

### Or More of These Gases May Be Used.

Among the above-mentioned temperatures, the processing temperature for processing the substrate is, for example, 300 to 550 degrees C. The processing pressure of the first process gas is 1 to 2000 Pa. The supply flow rate of the first process gas is 0.1 to 5.0 slm. The processing pressure of the second process gas is 1 to 4000 Pa. The supply flow rate of the second process gas in the MFC 241b is 0.1 to 2.5 slm. The supply flow rate of the inert gas is 0.01 to 5 slm.

In this specification, the notation of a numerical range such as “300 to 550 degrees C” means that a lower limit and an upper limit are included in the range. Therefore, for example, “300 to 550 degrees C” means “300 degrees C or more and 550 degrees C or less.” The same applies to other numerical ranges. Further, the processing temperature in this specification means the temperature of the wafers 200 or the temperature inside the process chamber 201, and the processing pressure means the pressure in the process chamber 201. The same applies to the following description.

In these embodiments, as shown in FIG. 5, in step A (from −2 seconds to 0 seconds), an inert gas is supplied to the process chamber 201. In step A, the opening degree of the APC valve 244 is set to 1. The process before −2 seconds is similar to that of step A.

In step B (from 0 seconds to 2 seconds), the second process gas is supplied to the process chamber 201. More specifically, the second process gas is supplied in short pulses during a part of the period of step B. As shown in FIG. 5, the opening degree of the APC valve 244 is reduced during a part of the period of step B. Then, in step B, the pressure in the process chamber 201 temporarily increases, but becomes equal to the original pressure (the pressure in step A).

More specific details regarding the timing at which the second process gas is supplied, the timing at which the opening degree of the APC valve 244 is changed, and the change in the pressure in the process chamber 201 in step B will be described later.

Step C (2 seconds to 4 seconds) is equivalent to step A, as shown in FIG. 5.

In step D (from 4 seconds to 6 seconds), the first process gas is supplied to the process chamber 201. Therefore, the pressure in the process chamber 201 temporarily increases in step D. However, in step D, the opening degree of the APC valve 244 is not changed, and the conductance is kept at the maximum.

Step E (6 seconds to 8 seconds) is similar to step A, as shown in FIG. 5.

The above series of steps A to E is called one cycle. As shown in FIG. 5, the cycle is repeated at least once or multiple times (two or more times) depending on the thickness of the film to be formed.

After the above-mentioned film-forming process is completed, the pressure in the process chamber 201 is returned to the normal pressure (atmospheric pressure). Specifically, for example, the process chamber 201 is purged with an inert gas, and the gas and the like remaining in the process chamber 201 are removed from the process chamber 201 (inert gas purging). Thereafter, the atmosphere in the process chamber 201 is replaced with an inert gas (inert gas replacement), and the pressure in the process chamber 201 is returned to the normal pressure (atmospheric pressure). Then, the wafers 200 are unloaded from the process chamber 201, consequently completing the substrate processing according to these embodiments.

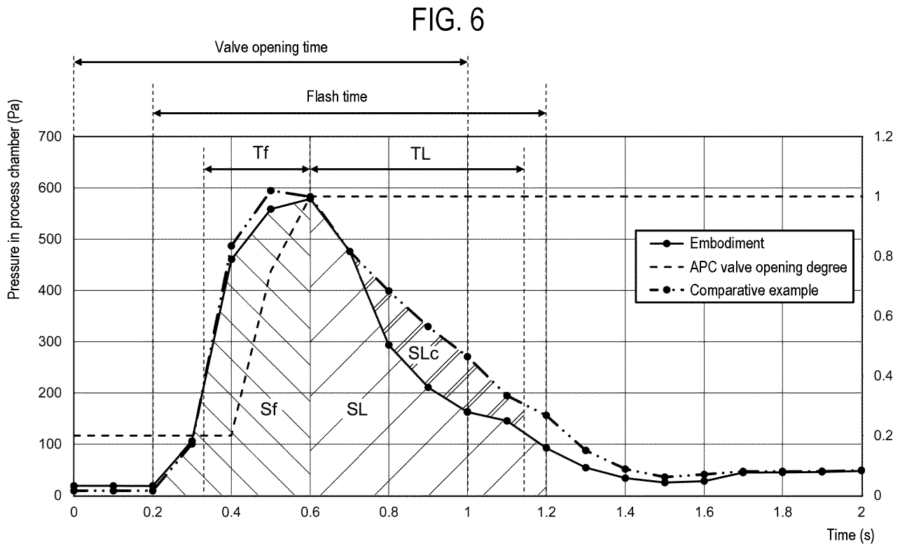

Next, the operation of the APC valve 244 and the change in the pressure in the process chamber 201 in step B will be described in detail with reference to FIG. 6.

### (Control of Exhaust System Conductance by Controller 121 of the Embodiments, and Change in Pressure in Process Chamber 201)

FIG. 6 shows the pressure in the process chamber 201 and the change over time in the opening degree of the APC valve 244 when the control operation in these embodiments is performed. FIG. 6 also shows the change over time in the pressure in the process chamber 201 when the control operation in the comparative example of these embodiments is performed.

In these embodiments, the controller 121 starts supplying the second process gas at the start of step B. More specifically, the controller 121 opens the valves 243b2, 612, 243c2, and 622 (hereinafter collectively referred to as supply valves) at the start time of step B (specifically, 0 seconds), thereby starting to allow the second process gas to flow into the process chamber 201. In these embodiments, the second process gas reaches the process chamber 201 0.2 seconds after the supply valves are opened, and the pressure in the process chamber 201 starts to increase. The pressure in the process chamber 201 reaches a peak at 0.6 seconds after the start of step B.

Furthermore, the controller 121 closes the supply valve after a predetermined time (1 second in these embodiments) has elapsed since the start of step B, thereby stopping the supply of the second process gas. The period during which the supply valve is open is called a valve open time. The period from when the second process gas reaches the process chamber 201 until the same time as the valve open time has elapsed, i.e., the period during which the gas is actually introduced into the process chamber, is called a flash time.

Here, the controller 121 changes the opening degree of the APC valve 244 along with the start of step B, thereby reducing the conductance. More specifically, the controller 121 sets the opening degree of the APC valve 244 to 0.2 from the start of the valve opening time to the start of the flash time. In these embodiments, the change in the opening degree from 1 to 0.2 is started before the start of step B (i.e., step A). The opening degree is stable at 0.2 at the start of step B.

Furthermore, the controller 121 increases the opening degree of the APC valve 244 after a predetermined time has elapsed since the start of step B. More specifically, the controller 121 starts increasing the opening degree before the time when the pressure reaches a peak. In these embodiments, the controller 121 increases the opening degree of the APC valve 244 from 0.2 to 1 during a period from 0.4 seconds to 0.6 seconds after the start of step B.

Furthermore, when increasing the opening degree of the APC valve 244, the controller 121 slows down the speed at which the opening degree is increased on the way. More specifically, the controller 121 slows down the speed at which the opening degree of the APC valve 244 is increased from 0.5 seconds to 0.6 seconds after the start of step B, compared to the speed at which the opening degree of the APC valve 244 is increased from 0.4 seconds to 0.5 seconds after the start of step B.

The controller 121 keeps the APC valve 244 fully open after 0.6 seconds from the start of step B. During this period, even within the valve opening time, the rate of introduction of a new gas into the process chamber 201 is significantly reduced, and the proportion of the gas (also called a reaction product gas, a reaction intermediate, or activated species) generated by decomposition of the second process gas increases in the process chamber, compared to the partial pressure of the second process gas. By fully opening the APC valve 244, the total pressure in the process chamber 201 decreases, and the exposure of the reaction product gas to the substrate is also suppressed. As a result, the controller 121 forms a film more uniformly on the inner surface of the hole of the substrate. In this context, the term ‘fully open’ includes a nominal or substantially fully open state that may have a restricted opening rather than a physically fully open position, for example to eliminate mechanical variations in the valve.

### (Change in Pressure in Process Chamber 201 in Comparative Example)

In a substrate processing apparatus 100 according to a comparative example, the controller 121 does not change the opening degree of the APC valve 244 even in step B. In other words, in the substrate processing apparatus 100 according to the comparative example, the controller 121 keeps the opening degree of the APC valve 244 fully open.

### (Operation)

In the substrate processing apparatus 100 of these embodiments, the controller 121 changes the opening degree of the APC valve 244 at the above-mentioned timing, which results in the following operation.

In the substrate processing apparatus 100 of these embodiments, there is a period in which the opening degree of the APC valve 244 is small even after the second process gas is supplied to the process chamber 201. Therefore, even if the supply amount of the second process gas is smaller than that in the comparative example before 0.6 seconds, the peak of the pressure in the process chamber 201 can be made equivalent to that in the comparative example.

In the comparative example, a larger amount of gas is obviously required than in these embodiments. Therefore, when the pressure reaches its peak, the pressure downstream of the APC valve 244 and the back pressure of the vacuum pump 246 rise. On the other hand, in these embodiments, such a pressure rise in the exhaust system is suppressed. Thus, the second process gas and the gas resulting from decomposition of the second process gas are exhausted from the process chamber 201 more quickly than in the comparative example 0.6 seconds after the opening degree of the APC valve 244 is maximized. Furthermore, according to the substrate processing apparatus 100 of these embodiments, the amount of the second process gas used is reduced compared to the comparative example.

The flash time in FIG. 6 is an example of “(a) step of introducing the process gas stored in the tank into the process chamber” in these embodiments. Furthermore, the process in which the opening degree of the APC valve 244 is not maximized during the period from 0.2 seconds to 0.6 seconds in FIG. 6 is an example of “(b) step of maintaining the conductance of the exhaust flow path of the process chamber at a non-zero value for a predetermined time after starting the introduction of the process gas into the process chamber” in these embodiments. The process in which the opening degree of the APC valve 244 is maximized at 0.6 seconds or later in FIG. 6 is an example of “(c) step of maximizing the conductance of the exhaust flow path of the process chamber after the predetermined time has elapsed” in these embodiments.

In addition, the process in which the controller 121 slows down the rate at which the opening degree of the APC valve 244 is increased from 0.5 seconds to 0.6 seconds after the start of step B is an example of “(b1) step of reducing the drive speed of the valve body before the APC valve is fully open” in these embodiments.

Incidentally, it is preferable that the controller 121 in these embodiments further controls the timing for changing the opening degree of the APC valve 244 and the opening degree so as to satisfy at least one of the following conditions.

### (Condition 1. Setting of Exposure Amount)

The controller 121 sets the amount of exposure of the substrate to the second process gas and its reaction product gas (hereinafter referred to as the “exposure amount”) after the pressure of the gas in the process chamber 201 reaches a peak to be four times or less than the exposure amount before the pressure of the gas in the process chamber 201 reaches a peak. The exposure amount is multiplied by the component force of the second process gas, or the like in the period during which the second process gas is exposed. In other words, the exposure amount is a value obtained by integrating the component force of the process gas, or the like exposed to the substrate over the period during which the process gas is exposed. The controller 121 controls the exposure amount SL after the pressure reaches a peak so that it is four times or less than the exposure amount Sf at which the pressure reaches a peak. The exposure amount is an amount that focuses on the pressure fluctuation in the process chamber 201 caused by the supply of the second process gas, and does not take into account the degree of decomposition of the second process gas. Therefore, the exposure amount can also be defined for gases that do not thermally decompose in a gas phase.

### (Condition 2. Setting of Pressure and Time)

The controller 121 sets a time TL during which the pressure in the process chamber 201 is 20% or more of the peak value after the pressure (total pressure) of the gas in the process chamber 201 reaches a peak to 4 times or less a time Tf during which the pressure in the process chamber 201 is 20% or more of the peak value before the pressure in the process chamber 201 reaches a peak. Condition 2 may be said to be another expression of condition 1 in the period during which the partial pressure of the inert gas can be ignored. Referring to FIG. 5, in the comparative example, the time Tf is 0.28 seconds, and the time TL is 0.55 seconds which is about twice as long as the time Tf. However, if the valve opening time is made shorter than 0.3 seconds for the reasons described below, it is considered that Tf will not exceed the valve opening time. Assuming that the valve opening time will be further shortened by this, it is considered preferable to specify the Tf/TL ratio as 4 times or less, rather than 2 times or less. If the Tf/TL ratio exceeds 4 times, no significant exhaust effect will be found compared to the comparative example.

(Condition 3. Setting of Time from Step (a) to Step (c))

The controller 121 sets the time from the start of step (a) to the start of step (c) to 1.3 seconds or less.

(Condition 4. Setting of Exposure Amount during Flash Time)

Compared to the case where the conductance is maintained at a constant value, the controller 121 increases the peak value of the partial pressure of the second process gas and its reaction product gas during the flash time and reduces the exposure amount after the pressure reaches a peak. In other words, the controller 121 controls the exposure amount SL after the pressure reaches a peak so that it is smaller than the exposure amount SLc after the pressure reaches a peak when the conductance is maintained at a constant value.

(Condition 5. Setting of Exposure Amount during Flash Time)

Compared to the case where the conductance is maintained at a constant value, the controller 121 increases the peak value of the partial pressure of the second process gas and its reaction product gas during the flash time and shortens the time until the pressure reaches 1/e (where e is the Napier's number) of the peak.

### (Condition 6. Setting of Flow Velocity and Temperature)

In the period during which the opening degree of the APC valve 244 is not maintained at the maximum, the controller 121 maintains a flow rate that ensures a flow velocity sufficient to deliver the second process gas to the substrate before the reaction for decomposing the second process gas and generating active species proceeds substantially. In these embodiments, the temperature at which the second process starts the decomposition reaction is lower than the temperature inside the process chamber 201. In many cases, the decomposition rate is strongly dependent on the temperature and the time.

### (Condition 7. Setting to Obtain Step Coverage)

The controller 121 sets the step coverage of the film formed on the inner surface of the hole in the substrate to 90% or more in the period during which the APC valve 244 is opened to the maximum at 0.6 seconds and later in FIG. 6. The aspect ratio (ratio of depth to diameter) of the channel hole of the 3D NAND flash memory can reach 1000.

### (Condition 8. Setting Exposure Amount During Flash Time)

Compared to the case where the conductance is maintained at a constant value, the controller 121 increases the peak value of the partial pressure of the second process gas or the exposure amount during the flash time, and decreases the peak value of the partial pressure of the reaction product gas (active species) or the exposure amount. The reaction product gas is highly active, and when generated in a gas phase, is deposited on the wafer as soon as it reaches the wafer. Therefore, it is believed that the high partial pressure of the reaction product gas reduces the film thickness inside the hole, especially at the bottom of the hole, where the gas is difficult to enter, and increases the film thickness on the flat portion of the surface of the wafer.

### (Test Examples and Results)

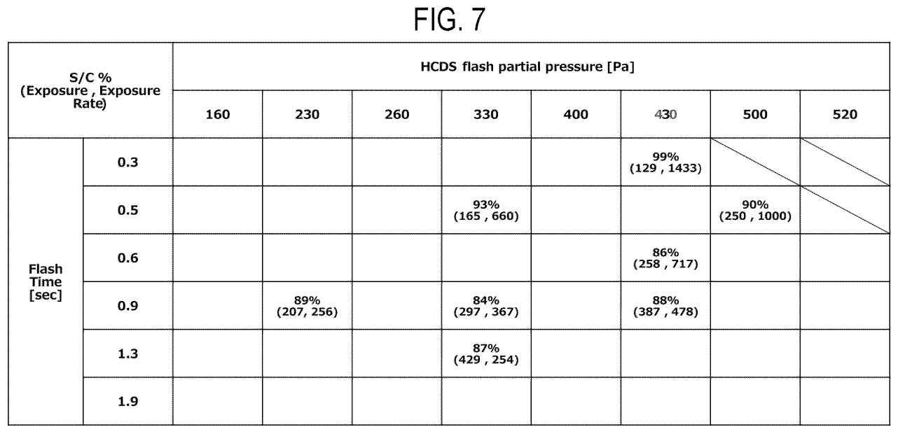

Next, the film formation results when the conditions in step B are changed will be described with reference to FIG. 7.

FIG. 7 shows the step coverage when the conditions in step B are changed using an apparatus corresponding to the substrate processing apparatus 100 according to these embodiments. More specifically, the step coverage of the film obtained by using chlorodisilane as the second process gas and changing the peak partial pressure of the second process gas and the open time of the supply valve (as in the flash time) while keeping the APC valve 244 fully open was evaluated. The step coverage is shown in the upper row of each cell, and the nominal exposure amount and nominal exposure rate per flash time are shown in the lower row. In addition, in the calculation of the partial pressure and the exposure amount, the partial pressure of a gas (inert gas, or the like) other than the second process gas and its reaction product gas was ignored as being sufficiently small.

The nominal exposure amount is calculated by multiplying the length of the flash time and the peak pressure value during the above-mentioned flash time. For example, in FIG. 7, when the flash time is 0.9 seconds and the peak pressure is 230 Pa, the nominal exposure amount is 207 Pa·s.

The nominal exposure rate is calculated by dividing the peak pressure value during the above-mentioned flash time by the length of the flash time. For example, in FIG. 7, when the flash time is 0.9 seconds and the peak pressure is 230 Pa, the nominal exposure rate is 256 Pa/s. These test results differ from theses embodiments in that the APC valve 244 is kept fully open throughout the entire flash time, but provide some suggestions regarding conditions suitable for these embodiments.

For example, it was confirmed that a good step coverage of 90% or more can be obtained only when the flash time is as follows, and that when the peak partial pressure of the second process gas or the like is the same, the shorter the flash time, the higher the step coverage tends to be. This suggests that the partial pressure of the decomposition products increases from about 0.5 seconds after the start of the flash time, possibly worsening the step coverage, and that when the flash time exceeds 1 second, it is difficult to obtain a good step coverage.

Moreover, even when comparing samples having similar nominal exposure amounts, it was confirmed that the higher the partial pressure and the shorter the flash time, the higher the step coverage tended to be.

In addition, it was confirmed that a good step coverage of 90% or more can be obtained only when the nominal exposure rate is 660 Pa/s or more, and that the higher the nominal exposure rate, the higher the step coverage tends to be. This suggests that, assuming a nominal exposure amount of 100 Pa·s or more, it is difficult to obtain a step coverage of 90% or more when the nominal exposure rate is 250 Pa/s or less.

According to the present disclosure, one or more of the following effects may be obtained.

### (Effects)

According to the substrate processing apparatus 100 of these embodiments, in step B, the opening degree of the APC valve 244 is maximized at 0.6 seconds or later, thereby lowering the partial pressure of the second process gas decomposed inside the process chamber 201. In addition, in the period from 0.2 seconds to 0.6 seconds in step B, the opening degree of the APC valve 244 is not maximized, so that the second process gas can be exposed to the substrate at a high partial pressure. This suppresses the decrease in step coverage caused by the thermally decomposed second process gas. In addition, compared to the case where the conductance of the exhaust flow path is maximized from the start of introduction of the second process gas, the partial pressure of the second process gas can be increased even if the amount of the second process gas introduced into the process chamber is small. Therefore, it is possible to reduce the consumption of the second process gas.

In addition, the disclosers of the present disclosure have found that the effects of the present disclosure may be more significantly achieved by having the controller 121 control the opening degree of the APC valve 244 so as to satisfy conditions 1 to 7.

As shown in the substrate processing apparatus 100 according to these embodiments, the conductance is obtained by controlling the opening degree of the APC valve 244. Therefore, in the substrate processing apparatus 100 according to these embodiments, the conductance of the exhaust system can be easily controlled compared to a case where the conductance is controlled by a method other than the method using the APC valve 244.

In the above-described embodiments, there has been described the example in which a film is formed using a batch-type substrate processing apparatus that processes a plurality of substrates at a time. The present disclosure is not limited to the above-described embodiments, but may also be suitably applied to, for example, a case where a film is formed using a single-substrate type substrate processing apparatus that processes one or several substrates at a time. Furthermore, in the above-described embodiments, there has been described the example in which a film is formed using the substrate processing apparatus including a hot wall type process furnace. The present disclosure is not limited to the above-described embodiments, but may be suitably applied to a case where a film is formed using a substrate processing apparatus including a cold wall type process furnace.

In the above description, the controller 121 has been described as a part of the configuration of the substrate processing apparatus 100. However, the technique according to the present disclosure is not limited thereto. The controller 121 may be separated from the substrate processing apparatus 100. That is, the technique according to the present embodiments is also applicable to a case where a processing apparatus that does not include a process chamber 34 processes a substrate by controlling the separate substrate processing apparatus 100 via a network or the like.

In the above description, the tank has been described as an example of the reservoir. However, the reservoir is not limited to the tank as long as it is configured to store a gas. For example, the portion of the supply pipe 232b between the valves 243b1 and 243b2 may be called the reservoir. In addition, the portion of the supply pipe 232c between the valves 243c1 and 243c2 may be called the reservoir.

In the above-described embodiments, there has been described the example in which a film is formed using the batch-type substrate processing apparatus that processes multiple substrates at a time. The present disclosure is not limited to the above-described embodiments, and may be suitably applied to, for example, a case where a film is formed using a single-substrate type substrate processing apparatus that processes one or several substrates at a time. In addition, in the above-described embodiments, there has been described the example in which a film is formed using the substrate processing apparatus including the hot-wall type process furnace. The present disclosure is not limited to the above-described embodiments, and may be suitably applied to a case where a film is formed using a substrate processing apparatus including a cold-wall type process furnace. In addition, the present disclosure is not limited thereto and may be applied to substrate processing apparatuses in general, such as a diffusion apparatus, an annealing apparatus, and an oxidation apparatus.

Even when using these substrate processing apparatuses, each process may be performed under the same processing procedures and processing conditions as in the above-described embodiments and modifications, and the same effects as in the above-described embodiments and modifications may be obtained.

The substrate is not limited to a wafer, but may be a photomask, a printed wiring board, a liquid crystal panel, a compact disk, a magnetic disk, or the like.

In each of the above-described embodiments, the processing executed by the CPU 121a by reading the software (program) may be executed by various processors other than the CPU 121a. Examples of the processor in this case include a PLD (Programmable Logic Device) whose circuit configuration can be changed after manufacture, such as an FPGA (Field-Programmable Gate Array) or the like, and a dedicated electric circuit which is a processor having a circuit configuration designed exclusively for executing a specific processing, such as an ASIC (Application Specific Integrated Circuit) or the like. The processing may be executed by one of these various processors, or may be executed by a combination of two or more processors of the same or different types (e.g., a plurality of FPGAs, and a combination of the CPU 121a and an FPGA). In addition, the hardware structure of these various processors is, more specifically, an electric circuit that combines circuit elements such as semiconductor elements and the like.

In addition, in each of the above-described embodiments, there has been described the example in which the processing program is stored (installed) in advance in the storage. However, the present disclosure is not limited thereto. The program may be provided in a form stored in a non-transitory storage medium such as a CD-ROM (Compact Disk Read Only Memory), a DVD-ROM (Digital Versatile Disk Read Only Memory), or a USB (Universal Serial Bus) memory. In addition, the program may also be downloaded from an external device via a network.

The embodiments of the present disclosure have been described above with reference to the attached drawings. However, it is apparent that a person with ordinary knowledge in the technical field to which the present disclosure pertains can conceive of various modifications or applications within the scope of the technical ideas recited in the claims. It should be understood that these also fall within the technical scope of the present disclosure.

According to the present disclosure in some embodiments, it is possible to suppress degradation of a step coverage caused by a thermally decomposed process gas.

While certain embodiments are described, these embodiments are presented by way of example, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is

1. A method of processing a substrate, comprising:
(a) introducing a process gas stored in a reservoir into a process chamber;
(b) maintaining a conductance of an exhaust flow path of the process chamber at a non-zero value for a predetermined time after starting the introduction of the process gas into the process chamber; and
(c) after (b), increasing the conductance of the exhaust flow path of the process chamber to a value greater than the non-zero value maintained in (b).

2. The method of claim 1, wherein the conductance is determined by an opening degree of a pressure regulator installed in the exhaust flow path.

3. The method of claim 1, wherein (a) is achieved by opening an opening/closing valve that connects the reservoir and the process chamber in a fluid communication manner.

4. The method of claim 1, wherein a time from the start of (a) to the start of (c) is 1.3 second or less.

5. The method of claim 1, wherein an exposure amount defined as a time integral of a pressure of the process gas after a pressure in the process chamber reaches a peak is four times or less than an exposure amount before reaching the peak.

6. The method of claim 1, wherein a time TL during which a pressure in the process chamber is at or above 20% of a peak after the pressure in the process chamber reaches a peak is four times or less than a time Tf during which the pressure in the process chamber is at or above 20% of the peak before reaching the peak.

7. The method of claim 4, wherein a time from the start of (a) to the start of (c) is 1 seconds or less.

8. The method of claim 1, wherein if a time in (a), which corresponds to a time during which an opening/closing valve connects the reservoir and the process chamber in a fluid communication manner is open, is defined as a flash time, a nominal exposure amount defined as a product of a length of the flash time and a peak of a pressure is 100 Pa·s or more, and a nominal exposure rate defined by dividing the peak of the pressure by the flash time is 500 Pa/s or more.

9. The method of claim 1, wherein if a time in (a), which corresponds to a time during which an opening/closing valve connects the reservoir and the process chamber in a fluid communication manner is open, is defined as a flash time, a peak value of a partial pressure of the process gas in the process chamber during the flash time is larger than when the conductance is maintained at a maximum, and an exposure amount defined as a time integral of a pressure of the process gas after a pressure in the process chamber reaches a peak during the flash time is smaller than when the conductance is maintained at a maximum.

10. The method of claim 1, wherein if the time in (a), which corresponds to the time during which an opening/closing valve connects the reservoir and the process chamber in a fluid communication manner is open, is defined as a flash time, a peak value of a partial pressure of the process gas in the process chamber during the flash time is larger than when the conductance is kept constant, and the time required for a pressure in the process chamber to decrease from a peak to 1/e (where e is the Napier's number) of the peak is shorter than when the conductance is kept constant.

11. The method of claim 1, wherein in (b), a flow rate is maintained to ensure a flow velocity which is sufficient to deliver the process gas to the substrate before a reaction that generates active species from the process gas substantially proceeds.

12. The method of claim 11, wherein the reaction is a decomposition reaction, and a temperature at which the process gas starts the decomposition reaction in a gas phase is lower than a temperature inside the process chamber.

13. The method of claim 2, wherein the pressure regulator is an APC valve having a nominal diameter of 150 A or more.

14. The method of claim 13, wherein (b) includes (b1) reducing a drive speed of a valve body before the APC valve is fully opened.

15. The method of claim 1, wherein (a) is repeated multiple times.

16. The method of claim 12, wherein in (c), the substrate is exposed to the process gas introduced in (a) or a reaction product gas of the process gas to form a film on an inner surface of a hole of the substrate.

17. The method of claim 13, wherein a step coverage of the film formed in (c) is 90% or more.

18. A method of manufacturing a semiconductor device, comprising:
(a) introducing a process gas stored in a reservoir into a process chamber;
(b) maintaining a conductance of an exhaust flow path of the process chamber at a non-zero value for a predetermined time after starting the introduction of the process gas into the process chamber; and
(c) after (b), maximizing the conductance of the exhaust flow path of the process chamber.

19. A substrate processing apparatus, comprising:
a process container includes a process chamber;
a process gas supply system configured to supply a process gas into the process chamber;
a process gas exhaust system including an exhaust flow path configured to exhaust the process gas from the process chamber;
an APC valve configured to be capable of changing the conductance of the exhaust flow path; and
a controller configured to control the process gas supply system, the process gas exhaust system, and the APC valve so as to perform:
(a) introducing the process gas stored in a reservoir into the process chamber;
(b) maintaining a conductance of the exhaust flow path of the process chamber at a non-zero value for a predetermined time after starting the introduction of the process gas into the process chamber; and
(c) after (b), maximizing the conductance of the exhaust flow path of the process chamber.

20. A non-transitory computer-readable recording medium storing a program that causes, by a computer, a substrate processing apparatus to perform a process comprising the method of Claim 1.
